(19) United States
(12) Patent Application Publication
(10) Pub. No.: US 2019/0041481 A1
(43) Pub. Date: Feb. 7, 2019

(54) MASSIVELY PARALLEL MAGNETIC RESONANCE IMAGING WHEREIN NUMEROUS OFF-SURFACE COILS ARE USED TO ACQUIRE PARTIALLY UNDER-SAMPLED MAGNETIC RESONANCE SIGNAL DATA

(71) Applicant: Muralidhara Subbarao, Stony Brook, NY (US)

(72) Inventor: Muralidhara Subbarao, Stony Brook, NY (US)

(21) Appl. No.: 15/668,742

(22) Filed: Aug. 4, 2017

(51) Int. Cl. G01R 33/561; G01R 33/341

(52) U.S. Cl. CPC G01R 33/5611; G01R 33/341

(57) ABSTRACT

A system and three methods are provided for massively parallel Magnetic Resonance Imaging of an object. They are based on using numerous, perhaps hundreds of, radio frequency receiver coils that measure Magnetic Resonance (MR) signal. In particular, the receiver coils are arranged both on-surface, i.e. relatively close and roughly parallel to the object surface, as well as off-surface, i.e. relatively distant or at a significant angle, such as 45 or 90 degrees, with respect to the object surface. The coils are arranged in a three-dimensional volume space at different positions, orientations, and distances, possibly in multiple layers. Each receiver coil is associated with a sensitivity map and provides partially under-sampled MR signal data with respect to frequency, phase, or k-space. The data from all coils are combined, using all the sensitivity maps in the image space or k-space, to obtain over-sampled data which is processed to reconstruct an unaliased image.

### 1. TECHNICAL FIELD

The present invention relates generally to magnetic resonance imaging (MRI) systems and methods, and in particular to a parallel Magnetic Resonance Imaging (pMRI) system and method for generating magnetic resonance images using one or more off-surface coils to acquire partially under-sampled Magnetic Resonance (MR) signal data. In prior art, on-surface coils are used to acquire under-sampled MR signal data. On-surface coils are coils that are placed close to, and parallel to, surface of an object being imaged. Off-surface coils are coils that are distant and/or substantially non-parallel to surface of an object being imaged.

### 2. BACKGROUND

Magnetic resonance imaging (MRI) is a safe medical imaging method used to generate images of tissue inside the human body. MRI is also used in other applications to image the inside of objects. An object to be imaged such as a part of the human body is placed in a controlled magnetic field, and excited by transmitting radio frequency (RF) pulses into the object to deposit RF energy in the object. The excited object in turn relaxes or gives out the deposited RF energy by emitting Magnetic Resonance (MR) signal in the form of radio frequency (RF) waves. The frequency and phase of these emitted RF waves are set to encode the 3D spatial location of different volume elements or voxels in the object. This encoding is done by appropriately controlling the magnetic field and the transmitted RF pulses in the spatial and temporal domains. The amplitude or energy of the RF wave emitted by a voxel characterizes a property of that voxel such as the hydrogen density of the tissue or material at that voxel. This amplitude or energy is represented as the image brightness at a pixel corresponding to that voxel in the image of the object being imaged. The RF waves emitted by excited voxels in the object are sensed by one or more RF receiver coils and their output is sampled and processed in a computer to generate a cross-sectional or 3D image of the object.

A description of the basic principles of pMRI relevant to this invention can be found in many publications. In particular, the following patents and publications provide background material to the present invention and the entire contents of the following items are incorporated herein by reference:
1. K. Setsompop, and L. L. Wald, “Method for Simultaneous Multi-Slice Magnetic Resonance Imaging”, U.S. Pat. No. 8,405,395, Date Mar. 26, 2013.
2. K. F. King, and D. Xu, “System and Method for Generating a Magnetic Resonance Image Using Compressed Sensing and Parallel Imaging”, U.S. Pat. No. 8,717,024, Date May 6, 2014.

3. J. Hamilton, D. Franson, and N. Seiberlich, “Recent Advances in Parallel Imaging for MRI”, Progress in Nuclear Magnetic Resonance Spectroscopy 101 (2017) 71-95. Elsevier B. V.
4. B. Keil, and L. L. Wald, “Massively Parallel MRI Detector Arrays”, Journal of Magnetic Resonance 229 (2013), 75-89.
5. M. Subbarao, “Field Image Tomography for Magnetic Resonance Imaging”, U.S. Pat. No. 8,378,682 B2, Date Feb. 19, 2013.
6. M. Subbarao, “Methods and Apparatuses for 3D Magnetic Density Imaging and Magnetic Resonance Imaging”, U.S. Pat. No. 8,456,164 B2, Date Jun. 4, 2013.
7. M. Griswold, Magnetic resonance imaging method and apparatus employing partial parallel acquisition, wherein each coil produces a complete k-space datasheet, U.S. Pat. No. 6,841,998, Date Jan. 11, 2005.

In parallel Magnetic Resonance Imaging (pMRI), multiple RF receiver coils are placed on the surface of the object at different spatial locations. They are used to sense the emitted RF waves simultaneously from different spatial locations on the surface of the object. These coils are called surface-coils or on-surface coils as they are placed relatively close to, and parallel to, the outer surface of the object. The MR signal from each of these surface coils is under-sampled with respect to the original image resolution along one or more dimensions. The under-sampling is done in one or more of the sampling spaces such as frequency, phase, or k-space coordinates. The under-sampled output of each RF receiver coil corresponds to an aliased image with a reduced field-of-view (FOV).

In pMRI, an un-aliased and full field-of-view (FOV) image of the object is reconstructed by processing the sensitivity-maps and the under-sampled MR signal from all of the RF receiver coils. The sensitivity of a given RF receiver coil for all the voxels of an object is termed as the sensitivity-map of that RF receiver coil. The sensitivity of an RF receiver coil to MR signal emitted by material in a volume element or voxel depends on the 3D spatial location of the voxel and the 3D location, orientation, and geometrical shape of the RF receiver coil. Therefore, each RF receiver coil located at a different 3D location and/or orientation will have a different sensitivity for a given voxel.

In pMRI, the maximum possible speed-up in the imaging scan time is theoretically equal to the number of RF receiver coils used, but in practice, it is less than that due to factors such as noise, mutual inductance, and low-sensitivity; for example, using 4 coils may provide an effective speed-up factor of only 2 or 3 instead of the maximum of 4. The actual speed-up factor corresponds to the factor by which the original image is under-sampled in the sampling space. This speed-up factor must be less than or equal to the number of RF receiver coils. Otherwise, it will not be possible to reconstruct the un-aliased, full field-of-view image from the under-sampled data.

In pMRI, the image scan time of a patient could be long, in the range of 15 to 30 minutes or longer. During this period, the patient is advised to stay still with minimal movement and minimal breathing to avoid motion blur. Staying still during the long period of pMRI image scanning is very uncomfortable to the patient and this period needs to be minimized. Also, the long duration of the image scanning period in pMRI reduces the number of patients who can be served in a day and increases the cost of the medical imaging service. For these reasons, it is very important to develop novel technologies for pMRI that can reduce the image scanning time.

The present invention provides a solution for significantly reducing the image scanning time in pMRI. This reduction in image scanning time is achieved by employing numerous, perhaps hundreds or more of, RF receiver coils. In particular, the present invention uses both on-surface coils used in prior art, as well as off-surface coils that have not been used in prior art for un-aliasing of under-sampled MR signal to reconstruct a full FOV image of an object.

Off-surface coils are RF receiver coils that are arranged in a configuration that is geometrically quite different from the on-surface coils used in prior art. Unlike on-surface coils, off-surface coils are those that are placed relatively distant from the surface of the object or/and they could be placed at a significant angle, such as 45 degrees or 90 degrees, with respect to the outer surface of the object. It has been verified by the author of this invention that these off-surface coils provide additional quantitative information on the image of the object; this new information is similar to the information provided by on-surface coils in both quantity and quality, but it is linearly independent. The novelty of the present invention lies in the technology to use numerous off-surface coils where each off-surface coil provides under-sampled MR signal data, and the technology to process all this data along with the sensitivity-map of each of the coil, and finally reconstruct an un-aliased image with full field-of-view, that makes it possible to increase the number of RF receiver coils dramatically, by a factor of 2 to 4 or more, and facilitate massive parallelism and dramatic speed-up in imaging time, by a factor of 2 to 4 or more. These off-surface coils may be arranged in a single layer or in multiple layers in three-dimensions at different positions, orientations, and distances from the surface of the object. In related prior art, only on-surface coils are used and therefore only limited information is collected and processed. In the method and the system provided here, both on-surface as well as off-surface receiver coils are used; therefore they collect and process much more information than in prior art resulting in faster imaging.

Use of off-surface coils also facilitates placing sufficient number of RF receiver coils in particular situations where the space for placing on-surface coils may be limited, for example when the shape of the object is large or has a complex shape. A large number of off-surface coils can be placed in a 3D volume space around the object, in multiple layers at different radial distances from the surface of the object as well as at different angles with respect to the surface of the object.

In summary, there is a big advantage in increasing the number of RF receiver coils in pMRI. The more numerous the coils, faster is the image scanning time in pMRI for a given image resolution and volume of the object to be imaged. The present invention provides a system and associated methods for pMRI that use a much larger number of RF receiver coils by using both on-surface and off-surface coils instead of limiting to only on-surface coils as in prior art. The effectiveness of this invention has been demonstrated by the author of this invention using a computer simulation method the details of which are presented in the following sections.

### 2.1 Drawbacks of Prior Art

An introduction to the principles of pMRI and a particular method for simultaneous multi-slice imaging is presented in U.S. Pat. No. 8,405,395, dated Mar. 26, 2013, by Setsompop and Wald. It employs a series of magnetic field gradient “blips” for slice encoding while simultaneously applying phase-encoding blips to achieve parallel imaging of multiple slices. A drawback of this method is that MR signal from only on-surface coils are acquired and processed. Off-surface coils are not used. Setsompop and Wald, in their U.S. Pat. No. 8,405,395, without stating but clearly intending, as always in prior art, assume that only on-surface coils are used and no off-surface coils are present. Therefore, in FIG. 1 of U.S. Pat. No. 8,405,395, the RF Coil 134 is shown to occupy a small thin space surrounding the outer surface of the object being imaged, a space just enough for only on-surface coils, that is, space just enough for only RF coils that are close to, and roughly parallel to the surface of the object being imaged. Similarly, in every patent and research publication in prior art, looking at the shape and space allocated to illustrate the RF receiver coils in the diagram of their pMRI systems, it can be verified that only on-surface coils are intended and used in their invention and research.

### Proof of the Advantages of the Present Invention

The author of the present invention has verified that the additional information provided by off-surface coils is very significant and comparable to that of on-surface coils. This will be described in detail later, but it is very important to note this result now to comprehend the discussion that follows. FIG. 14 in this patent application shows a plot of the image reconstructed using only off-surface coils configured as in FIG. 13; FIG. 14 also includes a plot of the image reconstructed using only on-surface coils configured as in FIG. 12. Note that, in order to make a strong claim to the advantage of using off-surface coils in this invention, the best possible configuration is allocated for on-surface coils (FIG. 12) and a very bad configuration (FIG. 13) is selected for off-surface coils. The four on-surface coils are close to, and parallel to, the outer surface of an object with a square cross section. In contrast, the four off-surface coils are perpendicular or at 90 degrees to the surface of the object, instead of say, at an angle of 30 degrees, 45 degrees, or 60 degrees. In spite of this “quite unfair comparison” between the on-surface coils and off-surface coils, with the off-surface coils being placed in a disadvantageous configuration relative to on-surface coils, it is seen in FIG. 14 that the image reconstructed using only off-surface coils is almost the same as the image reconstructed using only on-surface coils. The remaining small differences are due to round-off errors in numerical calculations. More details will be presented on this topic in a later section.

In prior art, the number of RF receiver coils is limited to the number of on-surface coils that can be accommodated on the outer surface of the object to be imaged. The additional information that can be acquired and processed to facilitate faster pMRI has been overlooked in prior art by researchers. This limits the factor of parallel imaging achieved which is roughly proportional to the number of coils used. Therefore, in prior art, the image scanning time will be much longer than that of the present invention. In the present invention, in addition to on-surface coils, numerous off-surface coils are placed in a 3D volume space surrounding the outer surface of the object. This increases the total number of RF receiver coils by a multiplicative factor of 2 or more and the imaging speed is increased by a similar factor of 2 or more.

Another pMRI method and system are disclosed in K. F. King, and D. Xu, “System and Method for Generating a Magnetic Resonance Image Using Compressed Sensing and Parallel Imaging”, U.S. Pat. No. 8,717,024, Date May 6, 2014. In this method, two sets of k-space data are used. One set includes calibration data and randomly under-sampled data. This data for each RF coil is converted to fully randomly sampled data by discarding a part of the calibration data randomly. Then a compressed sensing method is used to generate an aliased image. A second k-space data set is generated by inserting the portion of the calibration data and the unacquired data is synthesized. These results are combined to generate a complete k-space data set for each RF coil. This method also has the drawback that only on-surface coils are used; off-surface coils are not used. This can be verified by the same approach as before, as in the case of Setsompop and Wald (U.S. Pat. No. 8,405,395), by examining their drawings and specifications. In the patent of King and Xu (U.S. Pat. No. 8,717,024), examining the diagram of their pMRI system depicted in FIG. 1 there, a whole-body RF coil 56 and surface or parallel imaging coils 76 are illustrated. These coils are the RF receiver coils for receiving MR signal from the object. Both these coils 56 and 76 occupy a small thin space surrounding the outer surface of the object being imaged, confirming beyond any doubt that only on-surface coils are intended, contemplated, and used. Same conclusion can be drawn for other inventions and publications that provide a small space for accommodating RF receiver coils around the surface of the object being imaged. Therefore, the factor of parallel imaging is limited to the number of on-surface coils. The image scanning time in this case will be much longer than that of the present invention which uses off-surface coils in addition to on-surface coils.

A comprehensive review of current state of the art in pMRI is provided in J. Hamilton, D. Franson, and N. Seiberlich, “Recent Advances in Parallel Imaging for MRI”, Progress in Nuclear Magnetic Resonance Spectroscopy 101 (2017) 71-95. Elsevier B. V. This review presents several methods that have been employed to reduce image scanning time in pMRI. However, none of them use off-surface coils for MR signal reception thus limiting the factor of parallel imaging achieved. All the numerous methods and systems described in this recent publication can be substantially improved using the present invention through the use of off-surface coils in addition to on-surface coils used there.

A review of the theoretical and experimental basis of the trend towards using a large number of RF receiver coils to speed up pMRI is provided in B. Keil, and L. L. Wald, “Massively Parallel MRI Detector Arrays”, Journal of Magnetic Resonance 229 (2013), 75-89. This article clearly presents the difficulties associated with increasing the number of coils beyond 128 coils when only on-surface coils are used.

The author of the present invention has disclosed two other related inventions in the following two patents:
1. M. Subbarao, “Field Image Tomography for Magnetic Resonance Imaging”, U.S. Pat. No. 8,378,682 B2, Date Feb. 13, 2019.
2. M. Subbarao, “Methods and Apparatuses for 3D Magnetic Density Imaging and Magnetic Resonance Imaging”, U.S. Pat. No. 8,456,164 B2, Date Jun. 4, 2013.
   In the inventions above, magnetic field is measured in a 3D volume space using a large number of detectors or RF coils distributed in a 3D volume space. However, these two inventions are different from the present invention as they cannot use partially under-sampled MR signal along at least one dimension of frequency, phase, or k-space coordinates. They can only use fully under-sampled MR signal along at least one of the dimensions. The difference between partial and full under-sampling will be clarified below. In this entire patent, following conventional usage of the term in prior art, the term “under-sampled” will mean “partially under-sampled” but not “fully under-sampled”.

The difference between “partial under-sampling” and “full under-sampling” is clarified here. If P denotes the number of image pixels in a row which are reconstructed, C denotes the number of RF receiver coils that provide MR signal for reconstructing those P pixels, and S denotes the number of effective sample data points obtained from each coil, then, the following relation holds:
(number of coils C) times (number of samples per coil S) is equal to or greater than (number of pixels P), or

CS≥P.

In other words, the total number of sample data points acquired is C S and this total must be at least P in order to be able to reconstruct the P pixels. If S=1, then this case is termed as “full under-sampling”. Therefore, in the case of “full under-sampling”, each RF receiver coil provides only one effective sample data point, and the number of coils C required will be at least as large as the number of pixels P that are reconstructed, i.e. C≥P.

“Partial under-sampling” is the case when S>1 and S<P or 1<S<P. In this case, each RF coil yields at least 2 data points but less than the number of pixels P that are reconstructed. In this case C≥P/S. Following convention, in this patent, “under-sampling” will mean the same as “partial under-sampling”.

“Full sampling” or “Nyquist sampling” is the case when S=P. In this case, only one RF receiver coil is sufficient to acquire P data points and reconstruct all the P pixels in the image. However, more than one coil may be used to reduce the effects of noise. “Over sampling” is the case when S>P. These terms are clarified with the examples below:

1. Full under-sampling: S=1, C≥P; e.g.: C=6, S=1, P=6.

2. Partial under-sampling: 1<S<P, C≥P/S; e.g. C=3, S=2, P=6.

3. Partial under-sampling: 1<S<P, C≥P/S; e.g. C=2, S=3, P=6.

4. Full sampling or Nyquist sampling, C=1, S=P: e.g. C=1, S=6, P=6.

5. Over-sampling: C=1, S≥P; e.g. C=1, S=7, P=6.

The two methods in prior art disclosed in U.S. Pat. Nos. 8,378,682, and 8,456,164, which are referenced above, reconstruct the final MR image from the fully under-sampled MR signal along at least one of the three dimensions of frequency, phase, or k-space coordinates. Therefore, these two methods require too many RF coils. These methods are highly sensitive to noise and yield poor quality images. These earlier inventions are also very expensive to implement in practical applications. The present invention overcomes these drawbacks by acquiring only partially under-sampled MR signal data (i.e. 1<S<P) instead of fully under-sampled data (i.e. S=1 and C≥P) from multiple off-surface coils and processing all this data along with sensitivity maps of the coils to reconstruct an unaliased image of the object.

The pMRI methods in prior art fall into three broad categories—(a) image space methods, (b) k-space methods, and (c) methods with autocalibration. In image space methods, the results of processing under-sampled data from individual RF receiver coils are aliased images and they are combined in the image domain to obtain the final reconstructed image. In k-space methods, the results of processing under-sampled data from individual RF receiver coils are combined in the k-space domain. All the methods in these three categories in prior art use MR signal data from only on-surface coils; they do not use MR signal data from off-surface coils. The present invention enhances each methods in all the three categories through the acquisition and processing of MR signal data from off-surface coils, and optionally, on-surface coils as well.

The methods of the present invention are proven through standard computer simulation experiments used in prior art. For example, see FIG. 14 that compares the results of on-surface coils only used in prior art, and the use of off-surface coils used in the present invention. Except for small differences due to round-off errors in numerical calculations, both methods provide the same result. The difference is that the present invention permits the use of far more number of RF receiver coils by employing off-surface coils. Therefore, the present invention facilitates massive parallelism and much shorter image scan time compared to prior art.

An example of an image space method in prior art is sensitivity encoding or SENSE, and an example of a k-space method in prior art is simultaneous acquisition of spatial harmonics or SMASH. In the SENSE method, the under-sampled MR signal data is first Fourier transformed to produce an aliased image from each coil, and then the aliased image data are processed along with the sensitivity maps of all the receiver coils to generate an unaliased image. In the SMASH method, the under-sampled MR signal data from all receiver coils are processed in the k-space to synthesize or reconstruct the full k-space data prior to Fourier transformation. The full or over-sampled k-space data is generated by constructing a weighted combination of neighboring k-space lines acquired by the different receiver coils.

An example of a pMRI method with autocalibration is generalized autocalibrating partially parallel acquisitions or GRAPPA, as described, for example, in U.S. Pat. No. 6,841,998:
M. Griswold, Magnetic resonance imaging method and apparatus employing partial parallel acquisition, wherein each coil produces a complete k-space datasheet, U.S. Pat. No. 6,841,998, Date Jan. 11, 2005.
   GRAPPA is an extension of SMASH with variable density k-space sampling for autocalibration. In the GRAPPA method, k-space lines near the center of k-space are sampled at the Nyquist or higher frequency, in comparison to the under-sampling employed in the peripheral regions of k-space. These center k-space lines are referred to as the so-called autocalibration signal lines, which are used to determine the weighting factors that are utilized to synthesize, or reconstruct, the missing k-space lines. In particular, a linear combination of individual coil data is used to create the missing lines of k-space. The coefficients for the combination are determined by fitting the acquired data to the more densely sampled data near the center of k-space. After reconstructing the missing k-space lines, the image of the object is generated from the fully sampled k-space data.

### 3. BRIEF SUMMARY OF THE INVENTION

The present invention includes a system and three methods for parallel magnetic resonance imaging (pMRI) of an object to generate a magnetic resonance (MR) image of the object. The pMRI system and the three methods are summarized below.

3.1 the pMRI System

The present invention discloses a parallel magnetic resonance imaging (pMRI) system for producing a magnetic resonance (MR) image of an object. This system contains radio frequency (RF) receiver coils with at least one off-surface coil and zero or more on-surface coils. An on-surface coil is a coil that is both approximately parallel to, and close to, the surface of the object being imaged. In contrast, an off-surface coil is either substantially non-parallel to, and/or distant from, the surface of the object.

The pMRI system of the present invention comprises two main subsystems: a resonance assembly and a computer subsystem. The resonance assembly comprises:
a. a main magnet subsystem for polarizing the object,
b. a gradient coil subsystem for introducing magnetic gradients in the object to perform frequency encoding and phase encoding of MR signals emitted by the object,
c. zero or more on-surface coils, and one or more off-surface coils, for receiving radio frequency (RF) MR signals from the object; and,
d. an MR signal receiver configured to receive MR signals from both on-surface coils and off-surface coils.

The computer subsystem in the pMRI system is operatively connected to the resonance assembly. It is programmed to implement the following steps:
a. acquire partially under-sampled MR signal data of the object from each on-surface coil and off-surface coil in the resonance assembly,
b. generate over-sampled MR signal data of the object from partially under-sampled MR signal data of each on-surface coil and off-surface coil; and
c. generate an unaliased image of the object by processing over-sampled MR signal data generated in the previous step and the sensitivity maps associated with all on-surface coils and off-surface coils.

In the pMRI system of the present invention, one or more off-surface coils can be arranged at two or more different radial distances from the surface of the object; the pMRI system could also include one or more off-surface coils at two or more different angles with respect to the surface of the object. The pMRI system can further include a radio frequency transmitter (RF Transmitter) and a transmitter-receiver switch (T-R switch) that together can configure the off-surface coils and/or on-surface coils in the pMRI system, to transmitter mode, and/or receiver mode.

3.2 First pMRI Method Related to SENSE

The present invention also includes a method for producing an image of an object with a parallel magnetic resonance imaging (pMRI) system. This method is similar to the SENSE method in prior art, but includes off-surface coil data. The pMRI system used in acquiring data contains radio frequency (RF) receiver coils with at least one off-surface coil and zero or more on-surface coils. The steps of the method comprise:
a. estimating RF sensitivity maps of all on-surface coils and off-surface coils in the pMRI system,
b. acquiring, with the pMRI system, partially under-sampled magnetic resonance (MR) signal data from all on-surface coils, and all off-surface coils,
c. generating, with the pMRI system, one aliased image corresponding to a reduced field-of-view (FOV) of the object for each on-surface coil and each off-surface coil from the MR signal data of that coil obtained in step (b); and
d. generating, with the pMRI system, an un-aliased image corresponding to a full FOV of said object by processing all aliased images obtained in step (c) along with RF sensitivity maps of all on-surface coils and all off-surface coils obtained in step (a).

In this method, the MR signal data acquired in step (b) could be partially under-sampled with respect to phase-encoding, and/or frequency-encoding. In the last step (d), a regularization method such as Tikhonov regularization could be used to reduce the effects of noise. In regularization methods, ill-posed problems such as inverse problems are solved using data and smoothness constraints. For example, a weighted sum of two terms, one term indicating the closeness of the solution to observed data and another term indicating the smoothness of the solution, is optimized. The smoothness term could be the sum of the squared values of the pixel values of the estimated solution or first or second derivatives of the solution, etc. In the last step (d), a compressed sensing method prevalent in prior art could be used to generate the un-aliased image.

3.3 Second pMRI Method Related to SMASH

In another method of the present invention, the MR signal data is acquired and processed in k-space instead of image space. This method is similar to the SMASH method in pMRI but includes off-surface coil data. The steps of this method comprise:
a. estimating RF sensitivity maps of all on-surface coils and off-surface coils in the pMRI system,
b. acquiring, with the pMRI system, partially under-sampled magnetic resonance (MR) signal data in k-space from all on-surface coils, and all off-surface coils,
c. generating, with the pMRI system, over-sampled k-space data, by processing all partially under-sampled MR signal data acquired in step (b) and all RF sensitivity maps estimated in step (a); and
d. generating, with the pMRI system, an un-aliased image corresponding to a full FOV of the object by processing over-sampled k-space data obtained in step (c).

In this method, the MR signal data acquired in step (b) could be partially under-sampled with respect to phase-encoding, and/or frequency-encoding. In step (d), a regularization method could be used to reduce the effects of noise. In step (c), a compressed sensing method could be used to generate the over-sampled k-space data.

3.4 Third pMRI Method Related to GRAPPA

Another method of the present invention for pMRI is similar to GRAPPA which relies on auto-calibration of coil sensitivity maps by over-sampling the MR signal in a central region of k-space. No separate step is used for estimating the coil sensitivity maps. The steps of this method comprise:
a. acquiring, with the pMRI system, Magnetic Resonance (MR) signal data that is over-sampled in a central region of k-space from all on-surface coils and all off-surface coils,
b. acquiring, with the pMRI system, Magnetic Resonance (MR) signal data that is partially under-sampled in a peripheral region of k-space from all on-surface coils and off-surface coils,
c. generating, with the pMRI system, missing k-space data from all acquired k-space data in steps (a) and (b); and
d. generating, with the pMRI system, an un-aliased image corresponding to a full field-of-view (FOV) of the object by processing the full k-space data obtained in step (c).

In this method, the MR signal data acquired in step (b) could be partially under-sampled with respect to phase-encoding, and/or frequency-encoding. In step (d), a regularization method could be used to reduce the effects of noise. In step (c), a compressed sensing method could be used to generate the missing k-space data.

### 4. BRIEF DESCRIPTION OF THE DRAWINGS

Embodiments are illustrated by way of example and not limitation in the figures of the accompanying drawings. In these drawings, a reference number of same value indicates corresponding, analogous or similar elements.

FIG. 1 is a schematic block diagram of an exemplary parallel magnetic resonance imaging (pMRI) system in accordance with an embodiment. In particular, unlike pMRI systems in prior art, this pMRI system 200 includes off-surface coils 230 and associated customized components MR signal receiver 224 for on-surface and off-surface coils, controller 215 for off-surface and on-surface RF receiver coils, under-sampled to over-sampled data converter program component 240, and computer subsystem 206 with programs to control components in the pMRI system including off-surface coils 230.

FIG. 2 illustrates an example of on-surface coils 102 geometrically arranged close to, and parallel to, the surface of a 3D cylindrical object 101. A side-view of the configuration is shown. These on-surface coils 102 are circular and they receive radio frequency (RF) signals emitted by the 3D object.

FIG. 3 illustrates a top-view of on-surface coils 102 corresponding to the arrangement in FIG. 2.

FIG. 4 is a side-view of one example of an arrangement of RF receiver coils that includes both on-surface coils 102 and one type of off-surface coils 103, and a 3D cylindrical object 101. The on-surface coils 102 form an inner layer of coils that are close to, and roughly parallel to, the surface of the object 101. The off-surface coils 103 form an outer layer of coils that are distant from the surface of the object 101 along the radial direction. In particular, they are not close to the surface of the object.

FIG. 5 is a top-view of the arrangement of on-surface and off-surface coils corresponding to the arrangement in FIG. 4.

FIG. 6 is a side-view of another example of an arrangement of RF receiver coils that includes both on-surface coils 102 and a different type of off-surface coils 104, and a 3D cylindrical object 101. The on-surface coils 102 form an inner layer of coils that are close to, and roughly parallel to, the surface of the object 101. The off-surface coils 104 are not parallel but at a substantial angle of 90 degrees or perpendicular to the surface of the object 101.

FIG. 7 is a top-view of the arrangement of on-surface and off-surface coils corresponding to the arrangement in FIG. 6.

FIG. 8 is a top-view of another example of an arrangement of RF receiver coils that includes both on-surface coils 102 and different types of off-surface coils 105, and a 3D cylindrical object 101. The on-surface coils 102 form an inner layer of coils that are close to, and roughly parallel to, the surface of the object 101. The off-surface coils 105 are unlike on-surface coils 102. Some off-surface coils 105 are at 45 degrees with respect to the surface of the object 101, some other off-surface coils 105 are at 90 degrees with respect to the surface of the object 101, and the remaining off-surface coils 105 are in an outer layer parallel to but distant from the surface of the object 101.

FIG. 9 illustrates a flow-chart of the first method of the present invention for producing an image of an object with a parallel magnetic resonance imaging (pMRI) system with one or more off-surface coils. In contrast to related SENSE methods in prior art, the steps 720, 721, 722, and 713, are distinct features of this method of the present invention.

FIG. 10 illustrates a second method of the present invention for producing an image of an object with a parallel magnetic resonance imaging (pMRI) system with one or more off-surface coils. In contrast to related SMASH methods in prior art, the steps 740, 741, and 732, are distinct features of this method of the present invention.

FIG. 11 illustrates a third method of the present invention for producing an image of an object with a parallel magnetic resonance imaging (pMRI) system with one or more off-surface coils. In contrast to related GRAPPA methods in prior art, the steps 760, 761, 752, and 753, are distinct features of this method of the present invention.

FIG. 12 illustrates a top-view of an arrangement of on-surface coils 108 and a cube object 107. The four on-surface coils 108 represented by line segments represent square-shaped RF receiver coils. They are placed close to, and parallel to, the four faces of the cube object 107. This arrangement with only on-surface coils is used in an experiment to prove the advantages of the present invention. This arrangement of coils corresponds to the pMRI methods of prior art. The MR image reconstructed with this arrangement is shown in FIG. 14 which is found to be very close to the MR image reconstructed using only off-surface coils in a method of the present invention.

FIG. 13 illustrates the top-view of an arrangement of off-surface coils 109 and a cube object 107. The four off-surface coils 109 represented by line segments represent square-shaped RF receiver coils. They are placed perpendicular or at 90 degrees with respect to four faces of the cube object 107. This arrangement with only off-surface coils is used in an experiment to prove the advantages of the present invention. This arrangement of coils corresponds to a pMRI method of the present invention. The MR image reconstructed with this arrangement is shown in FIG. 14 which is found to be very close to the MR image reconstructed with only on-surface coils in a method of prior art.

FIG. 14 shows a comparative plot of one column of an MR image reconstructed by two different methods. One plot that is depicted with solid continuous line shows the reconstructed column of MR image using a method of prior art using only on-surface coils configured as in FIG. 12. Another plot depicted with dotted line shows the reconstructed column of MR image using a method of the present invention using only off-surface coils configured as in FIG. 13. The two plots are almost identical. The small differences are due to numerical round-off errors. This plot proves the advantages of the present invention.

FIG. 15 shows three off-surface coils that are concentric and mutually perpendicular in 3D for sensing MR signal along 3 mutually perpendicular directions. Off-surface coil 121 is perpendicular to X-axis, off-surface coil 122 is perpendicular to Y-axis, and off-surface coil 123 is perpendicular to Z-axis.

FIG. 16 shows an arrangement of off-surface coils placed in a 3D grid of size 3×3×3. At each grid point, three mutually perpendicular coils 125 as in FIG. 15 are placed. Each off-surface coil is designed to be small in diameter but highly sensitive to MR signal. This coil grid has numerous (81 in this case) off-surface coils that measure MR signal in a 3D volume space near the object to be imaged. This large number of off-surface coils facilitate massively parallel MRI.

### 5. DETAILED DESCRIPTION OF THE INVENTION

This section provides a full description of the present invention and of the manner and process of making and using the invention. The detailed description provided here uses the background material in prior found in numerous patents and publications including the following references cited earlier:
1. J. Hamilton, D. Franson, and N. Seiberlich, “Recent Advances in Parallel Imaging for MRI”, Progress in Nuclear Magnetic Resonance Spectroscopy 101 (2017) 71-95. Elsevier B. V.
2. K. Setsompop, and L. L. Wald, “Method for Simultaneous Multi-Slice Magnetic Resonance Imaging”, U.S. Pat. No. 8,405,395, Date Mar. 26, 2013.
3. K. F. King, and D. Xu, “System and Method for Generating a Magnetic Resonance Image Using Compressed Sensing and Parallel Imaging”, U.S. Pat. No. 8,717,024, Date May 6, 2014.
4. M. Griswold, Magnetic resonance imaging method and apparatus employing partial parallel acquisition, wherein each coil produces a complete k-space datasheet, U.S. Pat. No. 6,841,998, Date Jan. 11, 2005.

The principles and techniques of applying main magnetic field, gradient magnetic fields, radio frequency (RF) pulse sequences, and acquiring magnetic resonance (MR) signal data emitted from object being imaged in a pMRI system and method, are all described well in the above 3 references. Also, the principles and techniques of frequency encoding, phase encoding, k-space sampling, estimating sensitivity maps of RF receiver coils, SENSE method, SMASH method, GRAPPA method, as well as Compressed Sensing methods are described in the above references and the other patents and publications cited therein in the respective bibliographies. These principles and techniques will be applied and extended in the present invention for the case of a pMRI system with off-surface coils with associated components and to three pMRI methods that acquire and process MR signal data from off-surface coils.

Three main methods of the present invention are presented. The first method is related to the SENSE method in prior art, the second method is related to the SMASH in prior art, and the third method is related to the GRAPPA method in prior art. These three methods represent three broad categories and encompass almost all the methods in prior art including those in the review publication of Hamilton et al cited above. The principles and techniques of acquiring and processing data from off-surface cons is applicable to every pMRI method in prior art that uses only on-surface coils, including all the methods reviewed in the publication of Hamilton et al. The detailed description of the present invention provided here makes this clear.

5.1 Exemplary pMRI System of the Present Invention (with Components for Acquiring and Processing Partially Under-Sampled MR Signal Data from Off-Surface Coils)

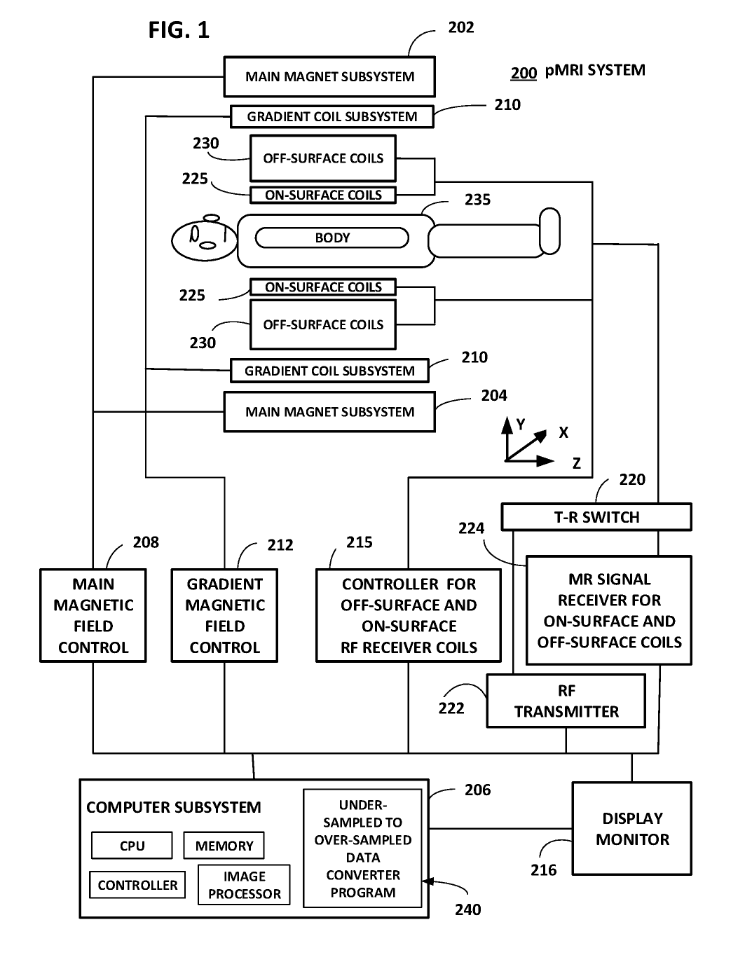

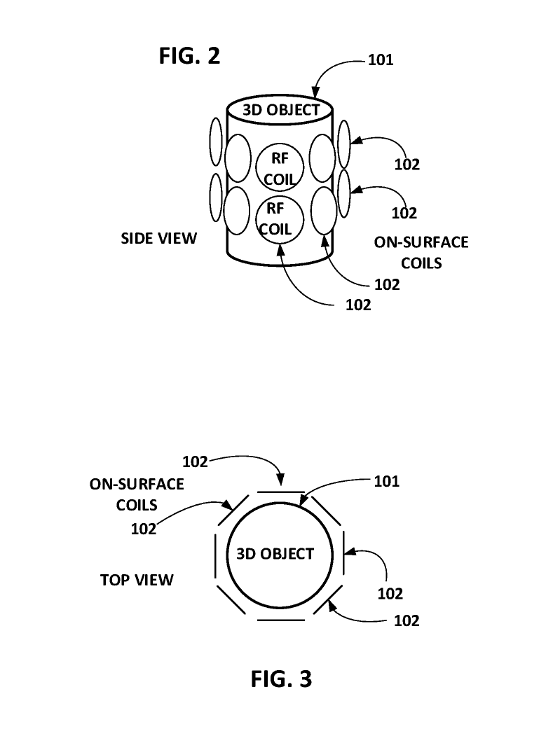

The present invention discloses a parallel magnetic resonance imaging (pMRI) system for producing a magnetic resonance (MR) image of an object. A schematic diagram of an exemplary system is shown in FIG. 1. The pMRI system 200 is an exemplary system of the present invention. In particular, it includes components for acquiring and processing partially under-sampled MR signal data from off-surface coils 230. Similar components are absent in related systems of prior art. The pMRI system of the present invention comprises two main subsystems: a resonance assembly with multiple components and a computer subsystem 206. The resonance assembly comprises the following components that are operatively connected with each other as shown in FIG. 1:
a. a main magnet subsystem 202 for polarizing an object 235 to be imaged,
b. a gradient coil subsystem 210 for introducing magnetic gradients in the object 235 to perform frequency encoding and phase encoding of MR signals emitted by the object 235,
c. zero or more on-surface coils 225, and one or more off-surface coils 230, for receiving radio frequency (RF) MR signals from the object 235,
d. an MR signal receiver 224 configured to receive MR signals from both on-surface coils 225 and off-surface coils 230,
e. main magnetic field control 208, gradient magnetic field control 212, controller 215 for off-surface coils and on-surface coils,
f. MR signal receiver 224 for on-surface and off-surface coils, RF transmitter 222 that sends suitable RF pulse sequences into the object 235, T-R switch 220 that is used to control RF pulse transmission and RF pulse reception of on-surface and off-surface coils, and
g. a display monitor 216 for displaying reconstructed MR images of the object.

The computer subsystem in the pMRI system 200 is operatively connected to the resonance assembly. It is programmed to control all components in the resonance assembly and implement the following steps:
a. acquire partially under-sampled MR signal data of the object from each on-surface coil and off-surface coil in the resonance assembly,
b. generate over-sampled MR signal data of the object from partially under-sampled MR signal data of each on-surface coil and off-surface coil; and
c. generate an unaliased image of the object by processing over-sampled MR signal data generated in the previous step and sensitivity maps associated with all on-surface coils and off-surface coils.

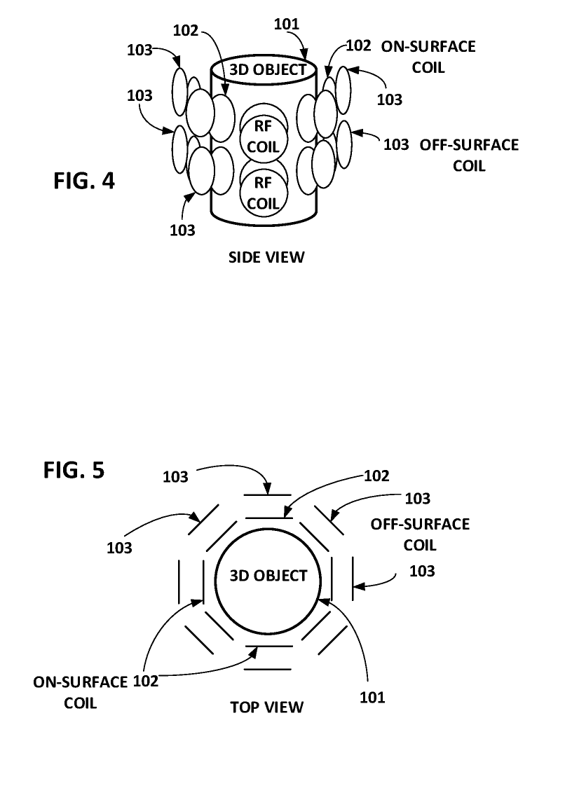

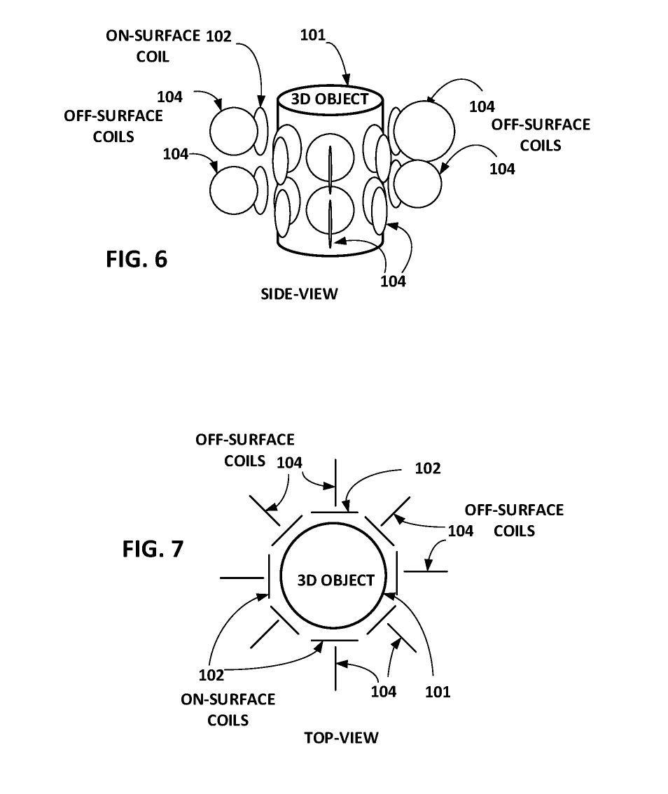

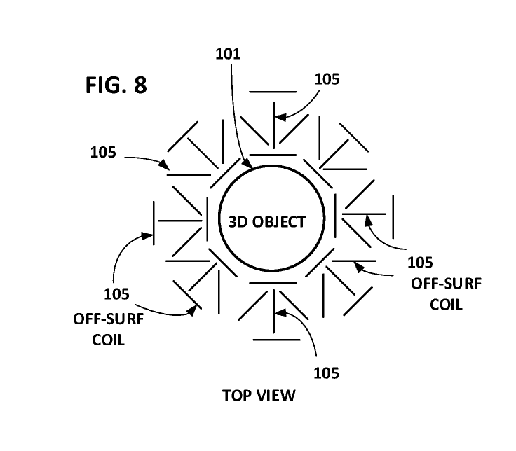

In the exemplary pMRI system 200 of the present invention, one or more off-surface coils are arranged at two or more different radial distances from the surface of the object; one example of such arrangement of off-surface coils 103 is shown in FIG. 4 and FIG. 5. The exemplary pMRI system 200 could also include one or more off-surface coils at two or more different angles with respect to the surface of the object; one example of such arrangement of off-surface coils 105 is shown in FIG. 8. In addition, the pMRI system may also include zero or more on-surface coils; some examples of this arrangement are shown in FIG. 4, FIG. 5, FIG. 6, FIG. 7, and FIG. 8.

The exemplary pMRI system 200 includes many novel components that are crucial to this invention that are not found in related systems in prior art. In particular, pMRI system 200 includes at least one and possibly numerous off-surface coils 230, an MR signal receiver 224 to receive a signal from both off-surface and on-surface coils, a controller 215 to control both off-surface and on-surface coils, and a computer subsystem 206 that includes a component 240 for converting partially under-sampled MR signal data obtained from all coils including off-surface coils to over-sampled data. Other components in the pMRI system 200 includes components that are found in prior art, such as a main magnet subsystem 204 for applying the main magnetic field to object 235 to be imaged, gradient coil subsystem 210 to apply gradient magnetic fields, on-surface coils 225, a T-R switch 220 that is used to select transmit or receive mode of operation of the on-surface and off-surface coils, main magnetic field control 208, gradient magnetic field control 212, and a display monitor 216 for displaying the reconstructed MR images.

In the exemplary pMRI system 200 in FIG. 1, the computer subsystem 206 sends control signals in an appropriate sequence to complete the following steps:
a. apply main magnetic field to the object to be imaged 235,
b. apply gradient magnetic field and RF transmit pulse sequence to generate partially under-sampled MR signals,
c. receive partially under-sampled MR signals from on-surface and off-surface coils,
d. process under-sampled MR signal data along with sensitivity maps of all on-surface and off-surface coils to generate over-sampled MR signal data,
e. reconstruct an unaliased and full field-of-view (FOV) image of the object from over-sampled MR signal data generated in step (d), and
f. display the reconstructed image on the display monitor 216.
   This system and its operation presented above should be compared with related systems in King et al and Setsompop et al cited above.
   5.2 First pMRI Method of the Present Invention (SENSE Type with Partially Under-Sampled MR Signal Data from Off-Surface Coils)

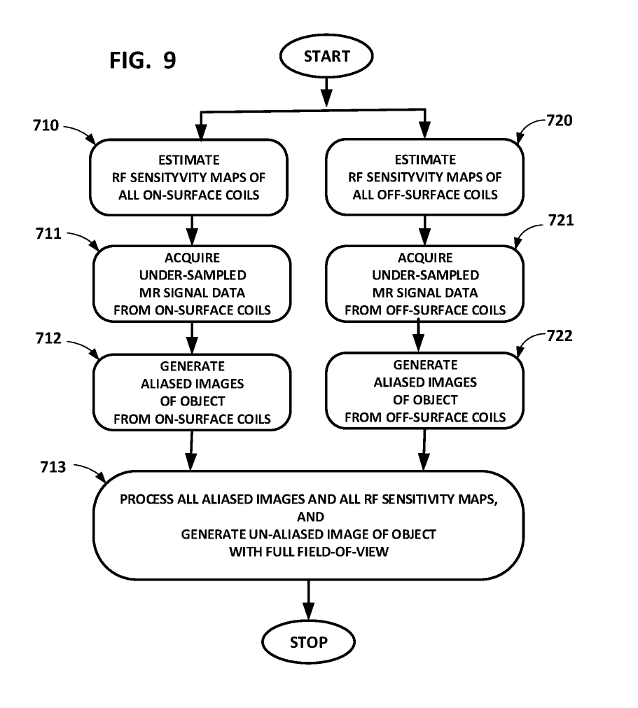

The present invention includes three novel methods for producing an image of an object with a parallel magnetic resonance imaging (pMRI) system having at least one off-surface coil. The first method of the present invention for reconstructing an image of an object using a pMRI system having at least one off-surface coil will be described next. The first method is similar to the SENSE method in prior art but it involves acquiring and processing partially under-sampled MR signal data from off-surface coils. The pMRI system associated with this method contains radio frequency (RF) receiver coils with at least one off-surface coil and zero or more on-surface coils. The steps of the method in an exemplary method of the present invention are shown in a flow-chart in FIG. 9. Referring to FIG. 9, the steps comprise:
a. Step 710 in FIG. 9: estimating RF sensitivity maps of all on-surface coils in the pMRI system,
b. Step 720 in FIG. 9: estimating RF sensitivity maps of all off-surface coils in the pMRI system,
c. Step 711 in FIG. 9: acquiring, with the pMRI system, partially under-sampled magnetic resonance (MR) signal data from all on-surface coils,
d. Step 721 in FIG. 9: acquiring, with the pMRI system, partially under-sampled magnetic resonance (MR) signal data from all off-surface coils,
e. Step 712 in FIG. 9: generating, with the pMRI system, one aliased image corresponding to a reduced field-of-view (FOV) of the object for each on-surface coil from the MR signal data of that coil obtained in step (c);
f. Step 722 in FIG. 9: generating, with the pMRI system, one aliased image corresponding to a reduced field-of-view (FOV) of the object for each off-surface coil from the MR signal data of that coil obtained in step (d); and
g. Step 713 in FIG. 9: generating, with the pMRI system, an un-aliased image corresponding to a full FOV of the object by processing all aliased images obtained in steps (e) and (f) along with RF sensitivity maps of all on-surface coils and all off-surface coils obtained in steps (a) and b. This full FOV image is displayed on a computer monitor. In this step, for each pixel of aliased image corresponding to a reduced FOV of the object, one set of linear system of equations are solved. In this linear system of equations, the coefficients of the equations are obtained from the RF sensitivity maps of all the on-surface and off-surface coils. The unknown values that are solved for and obtained are the values of the unaliased image pixels that correspond to the pixel in the aliased image. The right side of the equations are the values of the aliased image pixel values in the aliased images generated for each on-surface and off-surface coil.

In this method, the MR signal data acquired in step (c) and (d) could be partially under-sampled with respect to phase-encoding, and/or frequency-encoding. In steps (e) and (f), Fourier transformation of the MR data is performed. In the last step (g), a standard regularization method could be used to reduce the effects of noise. In the last step (g), a compressed sensing method could also be used to generate the un-aliased image.

### Proof of the Advantages of the Present Invention

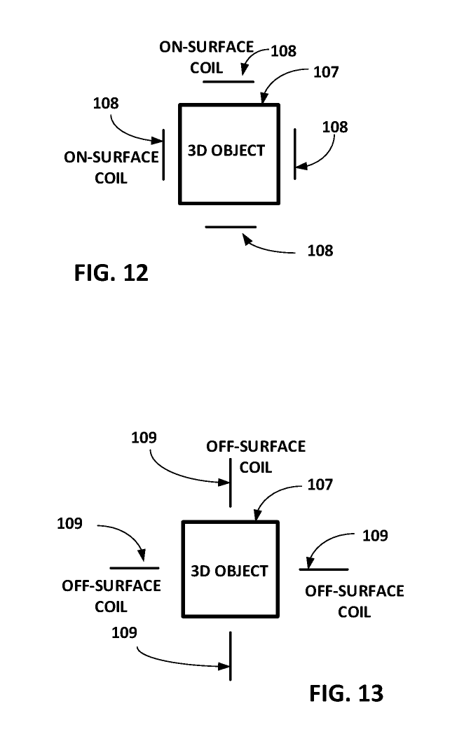

An experimental verification and validation of the method of the present invention using a standard computer simulation method used in the field of the invention will be described here. Performance of two pMRI methods, one standard SENSE method of pMRI found in prior art, and the first pMRI method of the present invention, are compared in a computer simulation experiment. In the SENSE method of prior art, a 3D cube object 107 and 4 square shaped on-surface coils 108 were used as in FIG. 12. The configuration used is as shown in FIG. 12. It shows a top view where the object 107 appears as a square and the square coils 108 appear as line segments parallel to the 4 sides of the square. In 3D, the coils are placed close to, and parallel to, outer 4 faces of the object. Therefore all the coils are on-surface coils.

In the first pMRI method of the present invention, the same 3D cube object 107 and the same four square shaped coils as above were used, but the coils were arranged as off-surface coils instead of on-surface coils. The configuration used in this case is as shown in FIG. 13. It shows a top view where the object 107 appears as a square and the square coils 109 appear as line segments perpendicular or at 90 degrees angle to the 4 respective sides of the square. In 3D, the coils are placed close to, and perpendicular to, outer four faces of the object. Therefore all the coils are off-surface coils.

The middle cross-section of the object was specified to be the magnetic resonance image of a human brain. The size of the image was 102 mm×102 mm, with a pixel size of 1 mm×1 mm. The coil sizes in all cases were 50 mm×50 mm. The distance of the coils from the surface of the object was 10 mm for on-surface configuration in FIG. 12. In the case of off-surface coils in FIG. 13, the distance of the nearest side of the coils from the surface of the object was 10 mm. Accurate radio frequency sensitivity map represented by a matrix of size 102×102 was computed for all the coils using the closed-form expressions for magnetic field components provided in (see Equations 4 to 6):
M. Misakian, “Equations for the Magnetic Field Produced by One or More Rectangular Loops of Wire in the Same Plane”, Volume 105, Number 4, July-August 2000, Journal of Research of the National Institute of Standards and Technology, pp. 557-564. (see Equations 4 to 6).

The existence of closed-from expressions for a rectangular coil is the reason for using square coils instead of circular coils in the experiments. In the case of circular coils, corresponding expressions are found to be elliptic integrals that need numerical approximations in the evaluation of the integrals. As an accurate comparison of the performance of off-surface coils against on-surface coils was desired, square coils with closed-form expressions for sensitivity maps were used instead of circular coils that would force numerical approximations in the experiment. In the case of circular coils, Equations 27 to 33 provide the relevant field equations in the following reference:
M. A. Azpurua, “A Semi-Analytical Method for the Design of Coil-Systems for Homogeneous Magneto-Static Field Generation”, Progress in Electro-Magnetics Research B, Volume 37, 171-189, 2012. (see Equations 27 to 33).

In order to make a standard comparison of the two competing methods, a test case considered in the following recent journal publication was used (see FIG. 5 in this publication below):
J. Hamilton, D. Franson, and N. Seiberlich, “Recent Advances in Parallel Imaging for MRI”, Progress in Nuclear Magnetic Resonance Spectroscopy 101 (2017) 71-95. Elsevier B. V. (see FIG. 5).

In this test case, number of coils used is C=4, and the imaging acceleration factor is R=3. This means that the field-of-view (FOV) of each coil is reduced to ⅓ of the full field-of-view. Therefore, the aliased images reconstructed using each single coil yields an image of size 34×102 instead of the original image size of 102×102. Three pixels in the original image overlap for each coil. These overlapping pixels in the original image are weighted by the corresponding sensitivity coefficients in the sensitivity map of the coil and summed up to provide the aliased image pixel sensed by the coil. Unfolding the four aliased images of size 34×102 provided by the four coils to reconstruct one unaliased image of size 102×102 involves solving a linear system of equations at each pixel of the aliased images. In this example, if the linear system of equations is represented by Ax=b, then the size of the coefficient matrix A is 4×3, size of the unknown vector x is 3×1 and represents the pixel values in the unaliased image, and size of b is 4×1 and represents the 4 values of aliased pixels, one each from the 4 coils. The condition number of the coefficient matrix A gives an indication of the numerical stability of the linear system of equations.

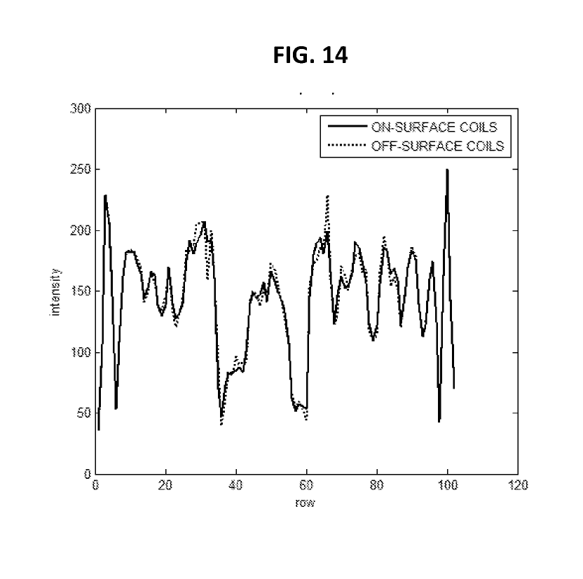

The middle slice of the object image was taken to be in the X-Y plane in a 3D Cartesian coordinate system X, Y, and Z. Therefore, sensitivity at a pixel was the magnitude of the magnetic field component in the X-Y plane. The coils were parallel to X-Z and Y-Z planes. First, the original MR image of a human brain was used to compute the aliased images of each coil using the sensitivity map of the corresponding coil. Then the aliased images of all 4 coils were taken as input and the unaliased image was reconstructed using the sensitivity maps of the 4 coils. The results of this experiment for the on-surface coils in FIG. 12 and for the off-surface coils in FIG. 13 are shown in FIG. 14. The actual output of the experiment was an 102×102 unaliased image. However this full image could not be presented in this patent application as gray-level images are not permitted in patent applications. Therefore, just one representative column at the center of the image, i.e. column 51, is plotted. In this plot, x-axis represents the pixel position or row index and y-axis represents the gray-level intensity of the reconstructed unaliased image.

In FIG. 14, it is found that the plots of the reconstructed image for the two methods being compared are almost the same. The plot of the output of the SENSE method in prior art that uses only on-surface coils as in FIG. 12 is shown with a continuous line. The plot of the output of the first pMRI method of the present invention that uses only off-surface coils as in FIG. 13 is shown with a dotted line. Both the continuous line and the dotted line overlap in most places indicating identical results for both the methods. In a few places, the two plots differ by a small amount. This is due to the round-off errors in numerical calculations. On the whole, off-surface coils alone can give results comparable to on-surface coils alone. Additional experiments were carried out with various coil configurations including configurations with a mixture of on-surface and off-surface coils. In all cases, results similar to the one presented here were obtained.

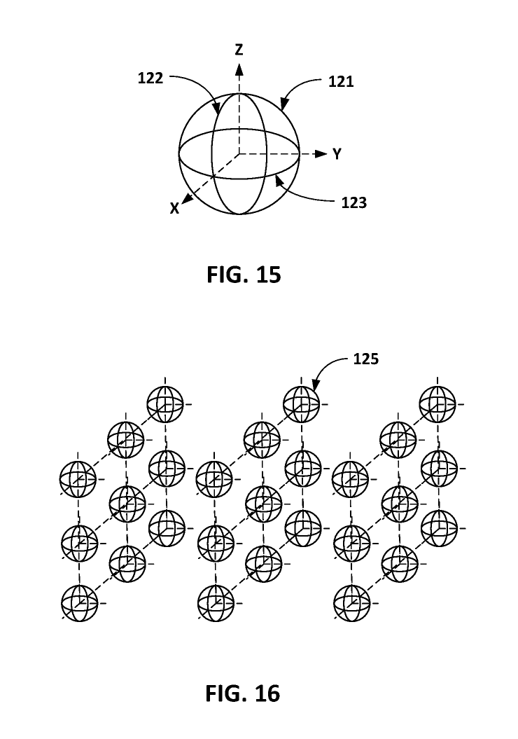

The results of this experiment verifies that the additional information provided by off-surface coils is very significant and comparable to that of on-surface coils. Therefore, numerous off-surface coils can be added to any pMRI system and the MR signals from these coils can be used in any pMRI method of prior art that uses only on-surface coils. While the number of on-surface coils is limited by the amount of space in a thin space around the surface of the object to be imaged, off-surface coils can occupy a large amount of space in a thick 3D volume space around the surface of the object. Therefore, the number of off-surface coils can be 2 to 10 times more than the on-surface coils. Consequently, massively parallel MR imaging becomes possible. One example of a 3D off-surface coil grid is shown in FIG. 16. In this grid, each element is a group of 3 mutually perpendicular coils as shown in FIG. 15. In this case, coils are small but highly sensitive. The coils could also be replaced by highly sensitive magnetic field detectors like Superconducting Quantum Interference Devices or SQUIDS used in ultra low-field MRI.

5.3 Second pMRI Method of the Present Invention (SMASH Type with Partially Under-Sampled MR Signal Data from Off-Surface Coils)

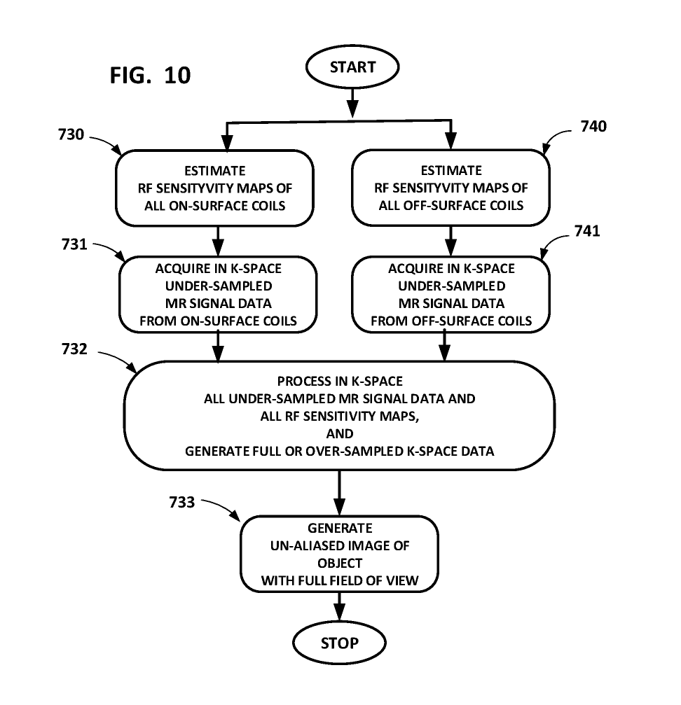

The second method of the present invention for reconstructing an image of an object using a pMRI system with at least one off-surface coil will be described next. In this method, the MR signal data is acquired and processed in k-space instead of image space. This method is similar to the SMASH method of pMRI in prior art, but this novel method includes acquiring and processing partially under-sampled MR signal data from off-surface coils. The steps of this method in an exemplary method of the present invention are shown in a flow-chart in FIG. 10. The steps of this method comprise:
a. Step 730 in FIG. 10: estimating RF sensitivity maps of all on-surface coils in the pMRI system,
b. Step 740 in FIG. 10: estimating RF sensitivity maps of all off-surface coils in the pMRI system,
c. Step 731 in FIG. 10: acquiring in k-space, with the pMRI system, partially under-sampled magnetic resonance (MR) signal data in k-space from all on-surface coils,
d. Step 741 in FIG. 10: acquiring in k-space, with the pMRI system, partially under-sampled magnetic resonance (MR) signal data in k-space from all off-surface coils,
e. Step 732 in FIG. 10: generating, with the pMRI system, over-sampled k-space data, by processing all partially under-sampled MR signal data acquired in steps (c) and (d) and, all RF sensitivity maps estimated in steps (a) and (b); and
f. Step 733 in FIG. 10: generating, with the pMRI system, an un-aliased image corresponding to a full FOV of the object by processing over-sampled k-space data obtained in step (e).

In this method, the MR signal data acquired in steps (c) and (d) could be partially under-sampled with respect to phase-encoding, and/or frequency-encoding. In step (e), missing or omitted k-space sample data is generated from partially under-sampled k-space data acquired in steps (c) and (d) by linearly combining neighboring k-space data acquired by different coils based on the RF sensitivity maps estimated in steps (a) and (b). In step (f), a regularization method could be used to reduce the effects of noise. In step (e), a compressed sensing method could be used to generate the over-sampled k-space data.

5.4 Third pMRI Method of the Present Invention (GRAPPA Type with Partially Under-Sampled MR Data from Off-Surface Coils)

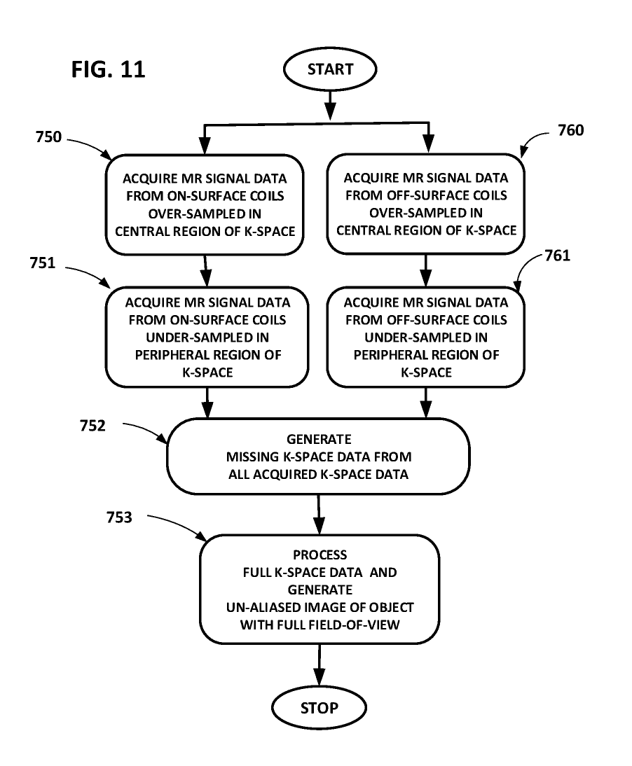

Another method of the present invention is described for producing an image of an object using a pMRI system having at least one off-surface coil. This third method of the present invention is related to the second method of the present invention in that data acquisition and processing are done in k-space; however, it differs from the second method as it involves auto-calibration of coil sensitivity maps by over-sampling the MR signal in a central region of k-space. In the non-central or peripheral region of k-space, partial under-sampling of MR signal is done to speed-up image scan time. In incorporating this step of auto-calibration, this method is similar to GRAPPA method in prior art, but it differs from GRAPPA as partially under-sampled MR signal data is acquired from off-surface coils and processed to reconstruct an image of the object. No separate step is used for estimating the RF coil sensitivity maps. The steps of this method in an exemplary method of the present invention are shown in a flow-chart in FIG. 11. The steps of this method comprise:
a. Step 750 in FIG. 11: acquiring, with the pMRI system, Magnetic Resonance (MR) signal data that is over-sampled in a central region of k-space from all on-surface coils,
b. Step 760 in FIG. 11: acquiring, with the pMRI system, Magnetic Resonance (MR) signal data that is over-sampled in a central region of k-space from all off-surface coils,
c. Step 751 in FIG. 11: acquiring, with the pMRI system, Magnetic Resonance (MR) signal data that is partially under-sampled in a peripheral region of k-space from all on-surface coils,
d. Step 761 in FIG. 11: acquiring, with the pMRI system, Magnetic Resonance (MR) signal data that is partially under-sampled in a peripheral region of k-space from all off-surface coils,
e. Step 752 in FIG. 11: generating, with the pMRI system, missing k-space data from all acquired k-space data in steps (a), (b), (c), and (d); and
f. Step 753 in FIG. 11: generating, with the pMRI system, an un-aliased image corresponding to a full field-of-view (FOV) of the object by processing the full k-space data obtained in step (e).

In this method, the MR signal data acquired in step (b) could be partially under-sampled with respect to phase-encoding, and/or frequency-encoding. In step (d), a regularization method could be used to reduce the effects of noise. In step (c), a compressed sensing method could be used to generate the missing k-space data.

### 6. CONCLUSION

The present invention provides a system and associated methods for parallel Magnetic Resonance Imaging (pMRI) of an object. The invention is based on using numerous off-surface coils for acquiring partially under-sampled MR signals. The MR signals obtained from off-surface coils are used for image reconstruction in a manner similar to that of on-surface coils. Including off-surface coils in the pMRI system increases the number of RF coils and helps to shorten the image scan time. The advantages of the present invention has been proved with an experimental demonstration. Many adaptations and extensions of the present invention are possible that are within the scope and spirit of the present invention.

This written description of the present invention uses examples to disclose the invention, including the best mode, and also to enable any person skilled in the art to make and use the invention. The patentable scope of the present invention is defined by the claims, and may include other examples that occur to those skilled in the art. Such other examples are intended to be within the scope of the claims if they have structural elements that do not differ from the literal language of the claims, or if they include equivalent structural elements with insubstantial differences from the literal language of the claims. The order and sequence of any process or method steps may be varied or re-sequenced according to alternative embodiments.

While the description here of the methods, system, and examples contain many specificities, these should not be construed as limitations on the scope of the invention, but rather as exemplifications of preferred embodiments thereof. Further modifications and extensions of the present invention herein disclosed will occur to persons skilled in the art to which the present invention pertains, and all such modifications are deemed to be within the scope and spirit of the present invention as defined by the appended claims and their legal equivalents thereof.

What is claimed is:

1. A parallel magnetic resonance imaging (pMRI) system for producing a magnetic resonance (MR) image of an object, said pMRI system comprising:
a) a resonance assembly for generating MR signals from said object comprising:
(i) a main magnet subsystem for polarizing said object,
(ii) a gradient coil subsystem for introducing magnetic gradients in said object to perform frequency encoding and phase encoding of MR signals that are emitted by said object,
(iii) one of zero, one, and a plurality of, on-surface coils for receiving radio frequency (RF) MR signals from said object wherein an on-surface coil is a coil that is both approximately parallel to and close to surface of said object being imaged, and each on-surface coil being associated with a sensitivity map that characterizes that coil's sensitivity to MR signals from different locations in said object,
(iv) at least one off-surface coil for receiving radio frequency MR signals from said object wherein an off-surface coil is a coil that is at least one of nonparallel to, and distant from, the surface of said object, and each off-surface coil being associated with a sensitivity map that characterizes that coil's sensitivity to MR signals from different locations in said object,
(v) an MR signal receiver configured to receive MR signals from both on-surface coils and off-surface coils in items (iii) and (iv); and,
b) a computer subsystem operatively connected to said resonance assembly in item (a) and programmed to:
(i) acquire partially under-sampled MR signal data of said object from each on-surface coil and off-surface coil in said resonance assembly,
(ii) generate over-sampled MR signal data of said object from partially under-sampled MR signal data of each on-surface coil and each off-surface coil acquired in item (b)(i); and
(iii) generate an unaliased image of said object by processing over-sampled MR signal data generated in item (b)(ii) and sensitivity maps associated with all on-surface coils and off-surface coils.

2. The pMRI system of claim 1 wherein said off-surface coils include a plurality of off-surface coils arranged at at least two different radial distances from the surface of said object.

3. The pMRI system of claim 1 wherein said off-surface coils include a plurality of off-surface coils arranged at at least two different angles with respect to the surface of said object.

4. The pMRI system of claim 1 wherein said off-surface coils include a plurality of off-surface coils arranged at at least two different radial distances and at least two different angles with respect to the surface of said object.

5. The pMRI system of claim 1 that further includes a radio frequency transmitter (RF Transmitter) and a transmitter-receiver switch (T-R switch) that together can configure at least one of said off-surface coils and said on-surface coils, to at least one of transmitter mode, and receiver mode.

6. A method for producing an image of an object with a parallel magnetic resonance imaging (pMRI) system, said pMRI system containing radio frequency (RF) receiver coils with at least zero on-surface coils and at least one off-surface coil, on-surface coil being a coil that is both approximately parallel to, and close to, surface of said object, and off-surface coil being a coil that is at least one of nonparallel to, and distant from, the surface of said object, the steps of the method comprising:
a) estimating RF sensitivity maps of all on-surface coils in said pMRI system,
b) estimating RF sensitivity maps of all off-surface coils in said pMRI system,
c) acquiring, with the pMRI system, partially under-sampled magnetic resonance (MR) signal data from all on-surface coils,
d) acquiring, with the pMRI system, partially under-sampled MR signal data from all off-surface coils,
e) generating, with the pMRI system, one aliased image corresponding to a reduced field-of-view (FOV) of said object for each on-surface coil from the MR signal data of that coil obtained in step (c),
f) generating, with the pMRI system, one aliased image corresponding to a reduced FOV of said object for each off-surface coil from the MR signal data of that coil obtained in step (d); and
g) generating, with the pMRI system, an un-aliased image corresponding to a full FOV of said object by processing all aliased images obtained in steps (e) and (f) along with RF sensitivity maps of all on-surface coils and all off-surface coils obtained in steps (a) and (b).

7. The method of claim 6 wherein MR signal data acquired in step (d) is partially under-sampled with respect to phase-encoding.

8. The method of claim 6 wherein MR signal data acquired in step (d) is partially under-sampled with respect to frequency-encoding.

9. The method on claim 6 wherein step (g) includes a regularization method to reduce the effects of noise.

10. The method of claim 6 wherein processing data in step (g) includes compressed sensing steps to generate said un-aliased image.

11. A method for producing an image of an object with a parallel magnetic resonance imaging (pMRI) system, said pMRI system containing radio frequency (RF) receiver coils with at least zero on-surface coils and at least one off-surface coil, on-surface coil being a coil that is both approximately parallel to, and close to, surface of said object, and off-surface coil being a coil that is at least one of nonparallel to, and distant from, the surface of said object, the steps of the method comprising:
a) estimating RF sensitivity maps of all on-surface coils in said pMRI system,
b) estimating RF sensitivity maps of all off-surface coils in said pMRI system,
c) acquiring, with the pMRI system, partially under-sampled magnetic resonance (MR) signal data from all on-surface coils,
d) acquiring, with the pMRI system, partially under-sampled MR signal data from all off-surface coils,
e) generating, with the pMRI system, over-sampled k-space data, by processing all partially under-sampled MR signal data acquired in steps (c) and (d), and all RF sensitivity maps estimated in steps (a) and (b); and
f) generating, with the pMRI system, an un-aliased image corresponding to a full FOV of said object by processing over-sampled k-space data obtained in step (e).

12. The method of claim 11 wherein MR signal data acquired in step (d) is partially under-sampled with respect to phase-encoding.

13. The method of claim 11 wherein MR signal data acquired in step (d) is partially under-sampled with respect to frequency-encoding.

14. The method of claim 11 wherein step (f) includes a regularization method to reduce the effects of noise.

15. The method of claim 11 wherein processing data in step (e) includes compressed sensing steps to generate over-sampled k-space data.

16. A method for producing an image of an object with a parallel magnetic resonance imaging (pMRI) system, said pMRI system containing radio frequency (RF) receiver coils with at least zero on-surface coils and at least one off-surface coil, on-surface coil being a coil that is both approximately parallel to, and close to, surface of said object, and off-surface coil being a coil that is at least one of nonparallel to, and distant from, the surface of said object, the steps of the method comprising:
a) acquiring, with the pMRI system, Magnetic Resonance (MR) signal data that is over-sampled in a central region of k-space from all on-surface coils in said pMRI system,
b) acquiring, with the pMRI system, Magnetic Resonance (MR) signal data that is over-sampled in a central region of k-space from all off-surface coils in said pMRI system,
c) acquiring, with the pMRI system, Magnetic Resonance (MR) signal data that is partially under-sampled in a peripheral region of k-space from all on-surface coils in said pMRI system,
d) acquiring, with the pMRI system, Magnetic Resonance (MR) signal data that is partially under-sampled in a peripheral region of k-space from all off-surface coils in said pMRI system,
e) generating, with the pMRI system, missing k-space data from all acquired k-space data in steps (a), (b), (c), and (d), and obtaining a full k-space data; and,
f) generating, with the pMRI system, an un-aliased image corresponding to a full field-of-view (FOV) of the object by processing the full k-space data obtained in step (e).

17. The method of claim 16 wherein MR signal data acquired in step (d) is partially under-sampled with respect to phase-encoding.

18. The method of claim 16 wherein MR signal data acquired in step (d) is partially under-sampled with respect to frequency-encoding.

19. The method of claim 16 wherein step (g) includes a regularization method to reduce the effects of noise.

20. The method of claim 16 wherein steps (e) and (f) use a compressed sensing method to generate missing k-space data.
